(19) United States
(12) Patent Application Publication
(10) Pub. No.: US 2025/0372366 A1
(43) Pub. Date: Dec. 4, 2025

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: KOKUSAI ELECTRIC CORPORATION, Tokyo (JP)

(72) Inventors: Yuki TAIRA, Toyama-shi (JP); Yusuke TERUI, Toyama-shi (JP)

(73) Assignee: KOKUSAI ELECTRIC CORPORATION, Tokyo (JP)

(21) Appl. No.: 19/089,904

(22) Filed: Mar. 25, 2025

(30) Foreign Application Priority Data
May 31, 2024 (JP) 2024-088857

(51) Int. Cl. H01L 21/02; C23C 16/52

(52) U.S. Cl. CPC H01L 21/0228; C23C 16/52; H01L 21/02167; H01L 21/0217; H01L 21/02274

(57) ABSTRACT

There is provided a technique that includes: forming a film, which contains a first element, a second element and a third element, on a substrate by performing a cycle a predetermined number of times, the cycle including performing: (a) supplying a first gas, which contains the first element and a halogen element, to the substrate; (b) supplying a second gas, which contains hydrogen and the second element that is different from the first element, to the substrate; (c) supplying a plasma-excited hydrogen-containing gas, which is different from the second gas, to the substrate; and (d) supplying a third gas, which contains the third element that is different from the first element and the second element, to the substrate, wherein (c) is performed after (a) and (b) and before (d).

### CROSS-REFERENCE TO RELATED APPLICATION

This application is based upon and claims the benefit of priority from Japanese Patent Application No. 2024-088857, filed on May 31, 2024, the entire contents of which are incorporated herein by reference.

### TECHNICAL FIELD

The present disclosure relates to a method of processing a substrate, a method of manufacturing a semiconductor device, a recording medium, and a substrate processing apparatus.

### BACKGROUND

In the related art, as a process of manufacturing a semiconductor, a process of supplying a predetermined gas to a substrate to form a film on the substrate may be performed.

### SUMMARY

Some embodiments of the present disclosure provide a technique capable of preventing desorption of a predetermined element during film formation, thus maintaining the predetermined element in a film at a desired composition ratio.

According to embodiments of the present disclosure, there is provided a technique that includes forming a film, which contains a first element, a second element and a third element, on a substrate by performing a cycle a predetermined number of times, the cycle including performing: (a) supplying a first gas, which contains the first element and a halogen element, to the substrate; (b) supplying a second gas, which contains hydrogen and the second element that is different from the first element, to the substrate; (c) supplying a plasma-excited hydrogen-containing gas, which is different from the second gas, to the substrate; and (d) supplying a third gas, which contains the third element that is different from the first element and the second element, to the substrate, wherein (c) is performed after (a) and (b) and before (d).

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus, suitably used in embodiments of the present disclosure, in which a portion of a process furnace is illustrated in a vertical cross-sectional view.

FIG. 2 is a schematic configuration diagram of the vertical process furnace of the substrate processing apparatus, suitably used in the embodiments of the present disclosure, in which a portion of the process furnace is illustrated in a cross-sectional view taken along line A-A of FIG. 1.

FIG. 3A is a perspective view illustrating electrodes, suitably used in the embodiments of the present disclosure, when attached to an electrode fixture. FIG. 3B is a diagram illustrating a positional relationship between a heater, the electrode fixture, the electrodes, protrusions for fixing the electrodes, and a reaction tube, suitably used in the embodiments of the present disclosure.

FIG. 4 is a schematic configuration diagram of a controller of the substrate processing apparatus, suitably used in the embodiments of the present disclosure, in which a control system of the controller is illustrated in a block diagram.

FIG. 5 is a diagram illustrating an example of a process sequence according to the embodiments of the present disclosure.

FIG. 6A is a diagram illustrating a state after execution of steps A and B, where a portion of a second gas bonds with dangling bonds on a first element. FIG. 6B is a diagram illustrating that, in step C, impurities such as a halogen element bonded to the first element and a hydrogen element bonded to a second element desorb, resulting in increased bonding between the first element and the second element. FIG. 6C is a diagram illustrating that the bonding between the first element and the second element increases even more as step C progresses further.

FIG. 7 is a diagram illustrating measured results and other data related to a film formed on a substrate.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### Embodiments of Present Disclosure

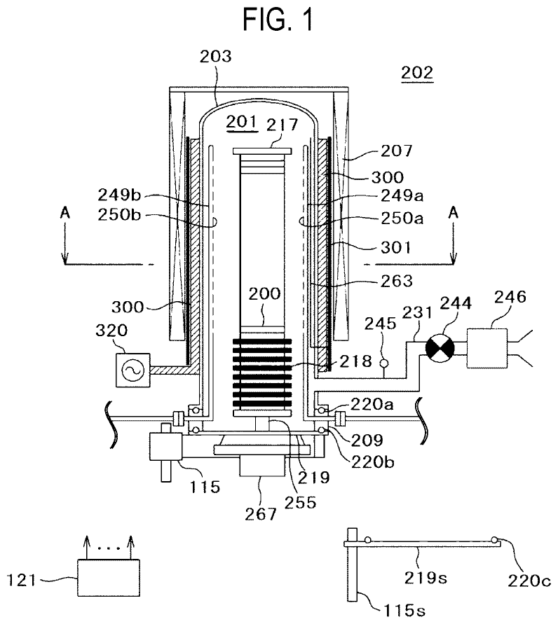

Hereinafter, embodiments of the present disclosure are described mainly with reference to FIGS. 1 to 6C. In addition, the drawings used in the following description are schematic, and dimensional relationships between respective elements, proportions of the respective elements, and others illustrated in the drawings may not match with those in reality. Further, the dimensional relationships between the respective elements, the proportions of the respective elements, and others may not match among multiple drawings.

### (Heater)

### (1) Configuration of Substrate Processing Apparatus

As illustrated in FIG. 1, a process furnace 202 includes a heater 207 serving as a temperature regulator (heating part). The heater 207 is formed in a cylindrical shape and is supported by a holding plate, thereby being installed vertically. The heater 207 also functions as an activator (heat exciter) that activates (excites) gases with heat.

An electrode fixture 301, which is described later, is disposed inside the heater 207, and furthermore, an electrode 300 of a plasma generator, which is described later, is disposed inside the electrode fixture 301. Furthermore, a reaction tube 203 is disposed concentrically with the heater 207 inside the electrode 300. The reaction tube 203 is made of a heat-resistant material such as quartz (SiO₂) or silicon carbide (SiC), and is formed in a cylindrical shape with a closed upper end and an opened lower end. A manifold 209 is disposed concentrically with the reaction tube 203 below the reaction tube 203. The manifold 209 is formed in a cylindrical shape with both upper and lower ends opened. The upper end of the manifold 209 is coupled to the lower end of the reaction tube 203 and is configured to support the reaction tube 203. An O-ring 220a is provided as a seal between the manifold 209 and the reaction tube 203. The reaction tube 203 and the manifold 209 mainly constitute a process container (reaction container). A process chamber 201 is formed in a hollow cylindrical region of the process container. The process chamber 201 is configured to be capable of accommodating multiple wafers 200 serving as substrates. In addition, the process container is not limited to the above configuration, and the reaction tube 203 alone may sometimes be referred to as the process container.

### (Gas Supplier)

Nozzles 249a and 249b are provided as first and second suppliers within the process chamber 201 so as to penetrate a sidewall of the manifold 209, respectively. The nozzles 249a and 249b are also referred to as first and second nozzles, respectively. The nozzles 249a and 249b are made of a heat-resistant material such as quartz or SiC. Gas supply pipes 232a and 232b are connected respectively to the nozzles 249a and 249b. Herein, the nozzles 249a and 249b are also referred to as R1 and R2, respectively.

The gas supply pipes 232a and 232b are provided, respectively, with mass flow controllers (MFCs) 241a and 241b, which are flow-rate controllers (flow-rate control parts), and valves 243a and 243b, which are opening/closing valves, in this order from an upstream of gas flow. Gas supply pipes 232c and 232f are connected respectively to the gas supply pipe 232a at a downstream of the valve 243a. Gas supply pipes 232d, 232e and 232g are connected respectively to the gas supply pipe 232b at a downstream of the MFC 241b. The gas supply pipes 232c to 232g are provided, respectively, with MFCs 241c to 241g and valves 243c to 243g in this order from an upstream of gas flow.

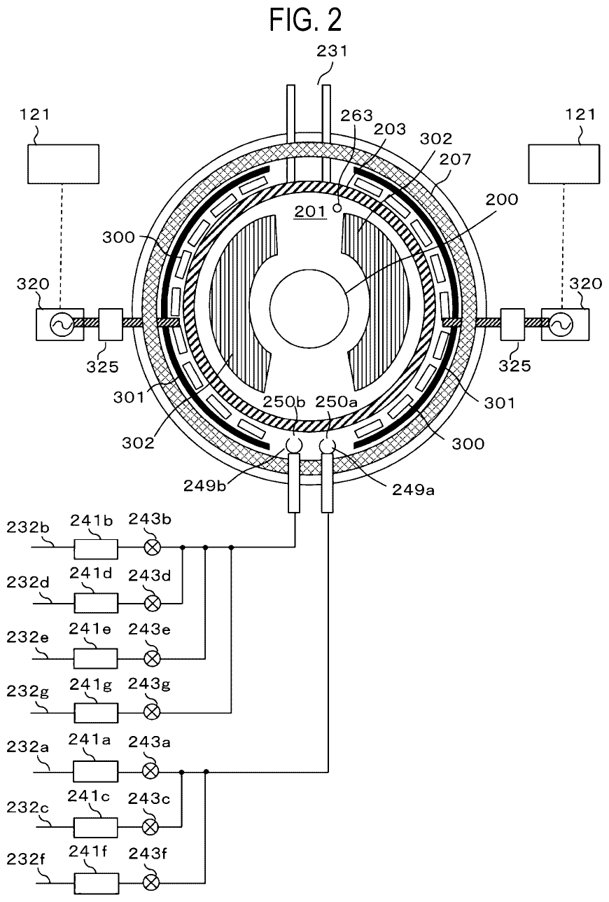

As illustrated in FIGS. 1 and 2, the nozzles 249a to 249b are each provided in an annular space in a plane view between an inner wall of the reaction tube 203 and the wafers 200, so as to extend upward along the inner wall of the reaction tube 203 from its bottom to top in a stacking direction (vertical direction) of the wafers 200. In other words, the nozzles 249a and 249b are respectively provided at a side of an end (peripheral edge) of each wafer 200 loaded into the process chamber 201, perpendicular to a surface (flat surface) of the wafer 200. Gas supply holes 250a and 250b for supplying gases are respectively provided at side surfaces of the nozzles 249a and 249b. The gas supply holes 250a are opened to face a center of the reaction tube 203, which enables supply of a gas toward the wafer 200. A plurality of gas supply holes 250a and 250b are provided respectively from a bottom to a top of the reaction tube 203.

In this way, in the present embodiments, gases are delivered through the nozzles 249a and 249b, which are disposed within an annular vertically elongated space, i.e., a cylindrical space, defined in a plane view by the inner sidewall of the reaction tube 203 and the ends (peripheral edges) of the multiple wafers 200 arranged within the reaction tube 203. Then, the gases are first ejected into the reaction tube 203 in a vicinity of the wafers 200 from the gas supply holes 250a and 250b of the nozzles 249a and 249b. Then, a main flow of gases within the reaction tube 203 is directed parallel to the surfaces of the wafers 200, i.e., in a horizontal direction. The gases that flowed on the surfaces of the wafers 200, i.e., residual gases after reactions, then flow toward an exhaust port, i.e., an exhaust pipe 231, which is described later.

A first gas, which contains a first element and a halogen element, is supplied from the gas supply pipe 232a into the process chamber 201 via the MFC 241a, valve 243a, and nozzle 249a.

A second gas, which contains hydrogen (H) and a second element that is different from the first element, is supplied from the gas supply pipe 232b into the process chamber 201 via the MFC 241b, valve 243b, and nozzle 249b.

A H-containing gas, which is different from the second gas, is supplied from the gas supply pipes 232c and 232d into the process chamber 201 via the MFCs 241c and 241d, valves 243c and 243d, gas supply pipes 232a and 232b, and nozzles 249a and 249b.

A third gas, which contains a third element that is different from the first and second elements, is supplied from the gas supply pipe 232e into the process chamber 201 via the MFC 241e, valve 243e, gas supply pipe 232b, and nozzle 249b.

An inert gas is supplied from the gas supply pipes 232f and 232g into the process chamber 201 via the MFCs 241f and 241g, valves 243f and 243g, gas supply pipes 232a and 232b, and nozzles 249a and 249b. The inert gas acts as a purge gas, a carrier gas, a dilution gas, and others.

A first gas supply system mainly includes the gas supply pipe 232a, MFC 241a, and valve 243a. A second gas supply system mainly includes the gas supply pipe 232b, MFC 241b, and valve 243b. A hydrogen-containing gas supply system mainly includes the gas supply pipes 232c and 232d, MFCs 241c and 241d, and valves 243c and 243d. A third gas supply system mainly includes the gas supply pipe 232e, MFC 241e, and valve 243e. An inert gas supply system mainly includes the gas supply pipes 232f and 232g, MFCs 241f and 241g, and valves 243f and 243g.

### (Substrate Support)

As illustrated in FIG. 1, a boat 217, which serves as a substrate support, is configured to support a plurality of, e.g., “25 to 200” wafers 200 in such a state that the wafers 200 are arranged at intervals in a horizontal posture and in multiple stages along the vertical direction with the centers of the wafers 200 aligned with one another. The boat 217 is made of a heat-resistant material such as quartz or SiC. Heat insulation plates 218, which are made of a heat-resistant material such as quartz or SiC, are supported in multiple stages at a bottom of the boat 217.

### (Plasma Generator)

Next, a plasma generator is described with reference to FIGS. 1 to 3B.

The electrode 300 for plasma generation is provided outside the reaction tube 203 (process container), i.e., outside (at an outer periphery of) the process chamber 201. By applying power to the electrode 300, gases may be subjected to plasma excitation, i.e., may be excited into a plasma state in an interior of the reaction tube 203, i.e., in an interior of the process chamber 201. Hereinafter, the excitation of gases into a plasma state may sometimes be simply referred to as plasma excitation. The electrode 300 is configured to generate a capacitively coupled plasma (CCP) within the reaction tube 203 (process container), i.e., within the process chamber 201, when radio frequency power (RF power) is applied thereto.

Specifically, as illustrated in FIG. 2, the electrode 300 and the electrode fixture 301 for fixing the electrode 300 are disposed between the heater 207 and the reaction tube 203.

Further, as illustrated in FIGS. 1 and 2, the electrode 300 and the electrode fixture 301 are provided in an annular space in a plane view between an inner wall of the heater 207 and an outer wall of the reaction tube 203 so as to extend from a bottom to a top of the outer wall of the reaction tube 203 in an arrangement direction of the wafers 200. The electrode 300 is provided parallel to the nozzles 249a and 249b. The electrode 300 and the electrode fixture 301 are arranged concentrically with the reaction tube 203 and the heater 207 in a plane view, and are disposed so as not to come into contact with the heater 207.

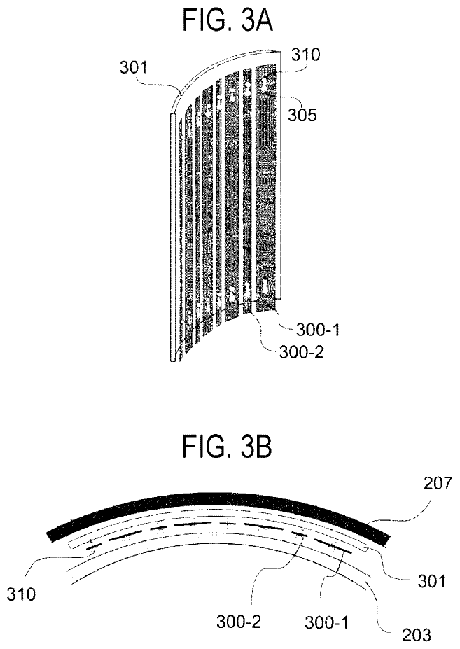

As illustrated in FIG. 2, a plurality of electrodes 300 are provided, and these electrodes 300 are fixed to an inner wall of the electrode fixture 301. More specifically, protrusions (hooks) 310 capable of hanging the electrodes 300 are provided at an inner wall surface of the electrode fixture 301, and openings 305, which are through-holes through which the protrusions 310 may be inserted, are provided at the electrodes. It is possible to fix the electrodes 300 to the electrode fixture 301 by causing the electrodes 300 to be caught by the protrusions 310 provided at the inner wall surface of the electrode fixture 301 via the openings 305. In addition, FIG. 2 illustrates an example in which nine electrodes 300 are fixed to one electrode fixture 301, forming one unit, and two such units are used in this configuration. FIGS. 3A and 3B illustrate an example in which eight electrodes 300-1 and 300-2 are fixed to one electrode fixture 301, forming one unit.

As illustrated in FIGS. 2 and 3A, the electrodes 300 include the first electrode 300-1 and the second electrode 300-2. The first electrode 300-1 is connected to a radio frequency power source (RF power source) 320 via a matcher 325, and an arbitrary potential is applied to the first electrode 300-1. The second electrode 300-2 is grounded to earth and becomes a reference potential (OV). Both the first and second electrodes 300-1 and 300-2 are configured as rectangular plate-shaped members in a front view. FIGS. 2, 3A and 3B illustrate the examples in which both the first electrode 300-1 and the second electrode 300-2 are provided in plurality. In the example of FIGS. 3A and 3B, four first electrodes 300-1 and four second electrodes 300-2 are provided.

When the RF power source 320 applies RF power between the first electrode 300-1 and the second electrode 300-2, a plasma is generated in a region between the first electrode 300-1 and the second electrode 300-2. This region is also referred to as a plasma generation region. As illustrated in FIG. 2, the electrodes 300 (first and second electrodes 300-1 and 300-2) are disposed in an arcuate shape in a plane view, and are equidistantly spaced apart from each other, i.e., with a distance (gap) between the adjacent first and second electrodes 300-1 and 300-2 being equal.

Radio frequency power, for example, within a range of 25 MHz or more to 35 MHz or less is input from the RF power source 320 to the electrode 300, thereby generating a plasma (active species) 302 within the reaction tube 203. This plasma generation enables the plasma 302 for substrate processing to be supplied to the surfaces of the wafers 200 from peripheries of the wafers 200.

The electrode 300 primarily constitutes a plasma generator (plasma exciter (exciter), plasma activator) that excites (activates) gases into a plasma state. The electrode fixture 301, matcher 325, and RF power source 320 may also be considered as included in the plasma generator.

### (Exhauster)

As illustrated in FIG. 1, the reaction tube 203 is provided with the exhaust pipe 231 for exhausting an internal atmosphere of the process chamber 201. The exhaust pipe 231 is connected to a vacuum pump 246, which serves as a vacuum exhauster, via a pressure sensor 245, which serves as a pressure detector (pressure detection component) that detects an internal pressure of the process chamber 201, and an auto pressure controller (APC) valve 244, which serves as an exhaust valve (pressure regulator). The APC valve 244 is configured to be capable of performing vacuum exhaust or stopping the vacuum exhaust within the process chamber 201 by opening or closing the valve while the vacuum pump 246 is in operation. The APC valve 244 is also configured to be capable of regulating the internal pressure of the process chamber 201 by adjusting valve opening degree based on pressure information detected by the pressure sensor 245 while the vacuum pump 246 is in operation. An exhaust system mainly includes the exhaust pipe 231, APC valve 244, and pressure sensor 245. The vacuum pump 246 may also be considered as included in the exhaust system.

### (Peripheral Devices)

A seal cap 219 is provided below the manifold 209 and serves as a furnace opening lid capable of airtightly closing an opening at a lower end of the manifold 209. An O-ring 220b is provided at an upper surface of the seal cap 219 and serves as a seal that abuts against the lower end of the manifold 209.

A rotator 267 for rotating the boat 217 is installed on a side of the seal cap 219 opposite to the process chamber 201. A rotating shaft 255 of the rotator 267 passes through the seal cap 219 and is connected to the boat 217. The rotator 267 is configured to rotate the wafers 200 by rotating the boat 217. A boat elevator 115, which serves as a lift, is configured to be capable of loading or unloading of the boat 217 into or out of the process chamber 201 by raising or lowering the seal cap 219.

The boat elevator 115 is configured as a transfer device (transfer mechanism) that transfers the boat 217, i.e., the wafers 200, into or out of the process chamber 201. Further, a shutter 219s is provided below the manifold 209 and serves as a furnace opening lid capable of airtightly closing the opening at the lower end of the manifold 209 while the seal cap 219 is being lowered by the boat elevator 115. An O-ring 220c is provided at an upper surface of the shutter 219s and serves as a seal that abuts against the lower end of the manifold 209. The opening/closing operation (such as lifting operation or rotating operation) of the shutter 219s is controlled by a shutter opening/closing mechanism 115s.

A temperature sensor 263 is installed as a temperature detector in the interior of the reaction tube 203. An internal temperature of the process chamber 201 achieves a desired temperature distribution by regulating a state of power supply to the heater 207 based on temperature information detected by the temperature sensor 263. The temperature sensor 263 is provided along the inner wall of the reaction tube 203, similar to the nozzles 249a and 249b.

### (Controller)

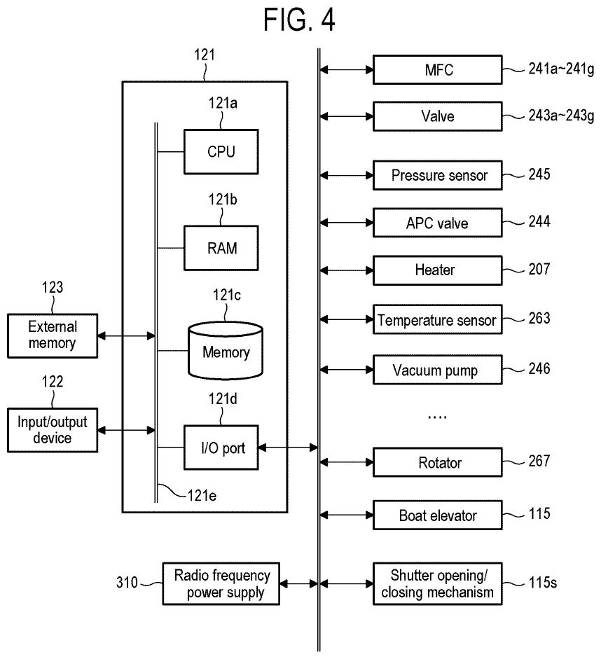

Next, a controller is described with reference to FIG. 4. As illustrated in FIG. 4, the controller 121, which is a control part (control device), is configured as a computer including a central processing unit (CPU) 121a, random access memory (RAM) 121b, memory 121c, and I/O port 121d. The RAM 121b, memory 121c, and I/O port 121d are configured to be capable of exchanging data with the CPU 121a via an internal bus 121e. The controller 121 is connected to an input/output device 122, which is configured by, for example, a touch panel, etc.

The memory 121c includes, for example, a flash memory, a hard disk drive (HDD), a solid state drive (SSD), and others. The memory 121c stores, in a readable manner, control programs for controlling the operation of a substrate processing apparatus, process recipes describing procedures, conditions, and others of film formation to be described later, and others. The process recipes are combinations that executes, by the controller 121, each procedure of various processes (film formation) to be described later in the substrate processing apparatus, thus achieving predetermined results, and function as programs. Hereinafter, the process recipes and control programs are collectively referred to simply as “program.” Further, the process recipes are also simply referred to as “recipe.” The term “program” as used herein may refer to a case of solely including the recipe, a case of solely including the control program, or a case of including both. The RAM 121b is configured as a memory area (work area) where programs, data, and others read by the CPU 121a are temporarily held.

The I/O port 121d is connected to, for example, the above-described MFCs 241a to 241g, valves 243a to 243g, pressure sensor 245, APC valve 244, vacuum pump 246, heater 207, temperature sensor 263, rotator 267, boat elevator 115, shutter opening/closing mechanism 115s, RF power source 320, and the like.

The CPU 121a is configured to read and execute the control program from the memory 121c and to read the recipe from the memory 121c, in response to, e.g., input of an operation command from the input/output device 122. The CPU 121a is configured to be capable of controlling, according to the recipe read, the control of the rotator 267, the flow rate regulating operations of various gases by the MFCs 241a to 241g, the opening/closing operations of the valves 243a to 243g, the opening/closing operation of the APC valve 244, the pressure regulating operation by the APC valve 244 based on the pressure sensor 245, the startup and shutdown of the vacuum pump 246, the temperature regulating operation of the heater 207 based on the temperature sensor 263, the forward/reverse rotation and rotational angle/rotational speed adjusting operation of the boat 217 by the rotator 267, the lifting operation of the boat 217 by the boat elevator 115, the opening/closing operation of the shutter 219s by the shutter opening/closing mechanism 115s, and the power supply of the RF power source 320.

The controller 121 may be configured by installing the above-described program recorded and stored in an external memory 123 onto the computer. The memory 121c and the external memory 123 are configured as computer-readable recording media. Hereinafter, these are collectively referred to simply as “recording medium.” The term “recording medium” as used herein may refer to a case of solely including the memory 121c, a case of solely including the external memory 123, or a case of including both. In addition, providing the program to the computer may be done using a communication means such as the Internet or a dedicated line without using the external memory 123.

### (2) Substrate Processing Process

An example of a process sequence of forming a film on the wafer 200 serving as a substrate, i.e., a film formation sequence, is described as a process in a manufacturing process of a semiconductor device, by using the above-described substrate processing apparatus. In the following description, the operation of each component constituting the substrate processing apparatus is controlled by the controller 121.

A film formation sequence of the present embodiments performs a process including:
forming a film, which contains a first element, a second element and a third element on the wafer 200, by performing a cycle a predetermined number of times (n times, where n is an integer of 1, or 2 or more), the cycle including performing:
(a) step A in which a first gas, which contains the first element and a halogen element, is supplied to the wafer 200;
(b) step B in which a second gas, which contains hydrogen (H) and the second element that is different from the first element, is supplied to the wafer 200;
(c) step C in which a plasma-excited H-containing gas, which is different from the second gas, is supplied to the wafer 200; and
(d) step D in which a third gas, which contains the third element that is different from the first and second elements, is supplied to the wafer 200,
wherein step C is performed after steps A and B and before step D.

Herein, the above-described process sequence may be represented as follows for convenience. The same notation is used in the descriptions of other embodiments, modifications, and others below.

$$( First Gas \to Purge \to Second Gas \to Purge \to Plasma - Excited H - containing Gas \to Purge \to Third Gas \to Purge ) \times n$$

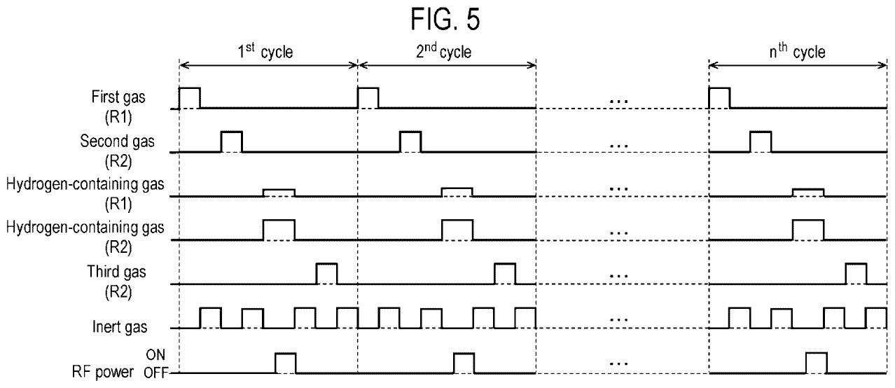

Further, the process sequence illustrated in FIG. 5 represents an example in which:
the first gas is supplied through the nozzle 249a (R1) in step A;
the second gas is supplied through the nozzle 249b (R2) in step B;
the H-containing gas is supplied through the nozzles 249a and 249b (R1 and R2) in step C; and
the third gas is supplied through the nozzle 249b (R2) in step D.

Furthermore, in the example illustrated in FIG. 5, in step C, the supply of the H-containing gas to the wafer 200 starts before the plasma excitation of H-containing gas starts.

These process sequences may be represented as follows.

$$\{ ( R 1 : First Gas ) \to Purge \to ( R 2 : Second Gas ) \to Purge \to [ ( R 1 , R 2 : H - containing Gas ) \to ( R 1 , R 2 : Plasma - Excited H - containing Gas ) ] \to Purge \to ( R 2 : Third Gas ) \to Purge \} \times n$$

The term “wafer” as used herein may refer to the wafer itself, or a stacked body including the wafer and a predetermined layer or film formed on a surface of the wafer. The term “surface of the wafer” as used herein may refer to the surface of the wafer itself, or a surface of a predetermined layer or the like formed on the wafer. When it is stated herein “forming a predetermined layer on the wafer”, it may refer to directly forming a predetermined layer on the surface of the wafer itself or forming a predetermined layer on a layer or the like formed on the wafer. The term “substrate” as used herein is synonymous with the term “wafer.”

The term “layer” as used herein refers to at least one selected from the group of a continuous layer and a discontinuous layer. For example, first to third layers to be described later may refer to continuous layers, discontinuous layers, or a combination of both.

When describing herein, for example, adsorption or reaction of each of the first to third gases with respect to the surface of the wafer 200, it may sometimes refer to embodiments in which they simply adsorb or react on the wafer surface in an undecomposed state as well as embodiments in which they decompose or ligands thereof desorb, leading to formation of intermediate species that then adsorb or react on the surface of the wafer 200.

### (Wafer Charging)

The boat 217 is charged with a plurality of wafers 200. After that, the shutter 219s may be moved by the shutter opening/closing mechanism 115s to open the opening at the lower end of the manifold 209. The wafers 200 include product wafers and dummy wafers.

### (Boat Loading)

Next, as illustrated in FIG. 1, the boat 217 supporting the plurality of wafers 200 is lifted by the boat elevator 115 and is loaded into the process chamber 201. In this state, the seal cap 219 seals the lower end of the manifold 209.

### (Pressure Regulation and Temperature Regulation)

After the boat loading is completed, the interior of the process chamber 201, i.e., a space where the wafers 200 exist, is vacuum-exhausted (decompression-exhausted) by the vacuum pump 246 to reach a desired pressure (degree of vacuum). At this time, the internal pressure of the process chamber 201 is measured by the pressure sensor 245, and the APC valve 244 is feedback-controlled based on the measured pressure information (Pressure Regulation). Further, the wafers 200 within the process chamber 201 are heated to reach a desired processing temperature by the heater 207. At this time, the state of power supply to the heater 207 is feedback-controlled based on the temperature information detected by the temperature sensor 263 so that the interior of the process chamber 201 achieves a desired temperature distribution (temperature regulation). Further, the rotation of the wafers 200 is initiated by the rotator 267. The exhaust of the process chamber 201 and the heating and rotation of the wafers 200 continue at least until the wafers 200 are completely processed.

### (Film Formation)

Next, the following steps A, B, C and D are sequentially executed.

### [Step A]

In step A, the first gas containing the first element and the halogen element is supplied to the wafer 200 within the process chamber 201.

Specifically, the valve 243a is opened to flow the first gas into the gas supply pipe 232a. The first gas regulated in flow-rate by the MFC 241a and is supplied into the process chamber 201 via the nozzle 249a and then discharged from the exhaust port 231a. At this time, the first gas is supplied to the wafer 200 (first gas supply). At this time, the valves 243f and 243g may be opened to supply an inert gas into the process chamber 201 via the respective nozzles 249a and 249b. In this step, the inert gas supplied via the nozzle 249a acts, for example, as a carrier gas and/or a dilution gas for the first gas. Further, the inert gas supplied via the nozzle 249b may serve to prevent invasion (backflow) of gas into the nozzle 249b, and may also be supplied to perform other functions such as regulating a gas flow within the process chamber 201.

Processing conditions in this step are exemplified as follows:
Processing temperature: 150 to 800 degrees C., specifically 180 to 700 degrees C., more specifically 400 to 700 degrees C.;
Processing pressure: 1 to 2,666 Pa, specifically 67 to 1,333 Pa;
First gas supply flow rate: 0.001 to 2 slm, specifically 0.01 to 1 slm;
First gas supply time: 1 to 120 seconds, specifically 1 to 60 seconds; and
Inert gas supply flow rate (for each gas supply pipe): 0 to 10 slm.

In addition, the notation of a numerical range such as “150 to 800 degrees C.” herein means that the lower limit value and the upper limit value are included in the range. Therefore, for example, “150 to 800 degrees C.” refers to “150 degrees C. or more and 800 degrees C. or less.” This applies similarly to other numerical ranges. Further, the processing temperature herein refers to a temperature of the wafer 200 or the internal temperature of the process chamber 201, and the processing pressure herein refers to the internal pressure of the process chamber 201, i.e., a pressure of the space where the wafer 200 exists. Further, the processing time refers to a time during which a process continues. Further, a pipe temperature refers to an internal temperature of a pipe. Further, if the supply flow rate includes 0 slm, “0 slm” refers to a case where no substance (gas) is supplied. These apply similarly to the following description.

By supplying the first gas (precursor gas) containing the first element and the halogen element to the wafer 200 under the above-described conditions, a first layer is formed on an outermost surface of the wafer 200 serving as an underlying layer. For example, when a chlorosilane-based gas containing silicon (Si) as the first element and chlorine (Cl) as the halogen element is used as the first gas, a Si-containing layer containing Cl is formed as the first layer on the outermost surface of the wafer 200. The first layer may be an adsorbed layer (physically adsorbed layer or chemically adsorbed layer) in which the first gas or a portion of the first gas is decomposed, or may be a Si-deposited layer containing Cl.

In the present embodiments, a case where a H-containing chlorosilane gas, which contains Si as the first element, Cl as the halogen element, and H, is used as the first gas is described as an example.

By supplying the first gas to the wafer 200 under the above-described conditions, Si—H bonds, Si—Cl bonds or the like are formed in the first layer.

After the first layer is formed, the valve 243a is closed to stop the supply of the first gas into the process chamber 201. Then, the process chamber 201 is vacuum-exhausted to remove residual gases and the like from the process chamber 201. At this time, the valves 243f and 243g are opened to supply an inert gas into the process chamber 201, purging the process chamber 201 with the inert gas. In addition, at this time, neither the first gas nor the second gas to be described later is supplied into the process chamber 201. In the present embodiments, a step in which the process chamber 201 is exhausted without the supply of the first and second gases may be referred to as step F.

The first gas may be, for example, a halosilane-based gas, which contains Si as the first element, corresponding to a main constituent element of the film formed on the wafer 200, and the halogen element in a single molecule. Examples of the halogen element may include chlorine (Cl), fluorine (F), bromine (Br), and iodine (I). Examples of the halosilane-based gas may include the above-described chlorosilane-based gas containing Si and Cl.

The first gas may be, for example, a H-containing chlorosilane gas such as monochlorosilane (SiH₃Cl) gas, dichlorosilane (SiH₂Cl₂) gas, or trichlorosilane (SiHCl₃) gas. One or more of these may be used as the first gas.

In addition to the chlorosilane-based gas, for example, a H-containing fluorosilane-based gas such as difluorosilane (SiH₂F₂) gas or trifluorosilane (SiHF₃) gas, a H-containing bromosilane-based gas such as dibromosilane (SiH₂Br₂) gas or tribromosilane (SiHBr₃) gas, or a H-containing iodosilane-based gas such as diiodosilane (SiH₂I₂) gas or triiodosilane (SiHI₃) gas may also be used as the first gas. One or more of these may be used as the first gas.

The first gas may be, for example, a non-H-containing halosilane-based gas such as tetrachlorosilane (SiCl₄) gas, hexachlorodisilane gas (Si₂Cl₆) gas, octachlorotrisilane (Si₃Cl₈) gas, tetrafluorosilane (SiF₄) gas, hexafluorodisilane (Si₂F₆) gas, tetrabromosilane (SiBr₄) gas, hexabromodisilane (Si₂Br₆) gas, tetraiodosilane (SiI₄) gas, or hexaiododisilane (Si₂I₆) gas. One or more of these may be used as the first gas. However, it is more desirable to use the above-described H-containing halosilane-based gas as the first gas.

The inert gas may be, for example, a nitrogen (N₂) gas, or a noble gas such as argon (Ar) gas, helium (He) gas, neon (Ne) gas, or xenon (Xe) gas. One or more of these gases may be used as the inert gas. This applies similarly to each step to be described later.

### [Step B]

After step A is completed, the second gas containing the second element, which is different from the first element, and hydrogen (H) in a single molecule is supplied to the wafer 200 within the process chamber 201, i.e., to the first layer formed on the wafer 200.

Specifically, the valve 243b is opened to flow the second gas into the gas supply pipe 232b. The second gas is regulated in flow-rate by the MFC 241b and is supplied into the process chamber 201 via the nozzle 249b and then discharged from the exhaust port 231a. At this time, the second gas is supplied to the wafer 200 (second gas supply). At this time, the valves 243f and 243g may be opened to supply an inert gas into the process chamber 201 through the respective nozzles 249a and 249b. In this step, the inert gas supplied through the nozzle 249b acts, for example, as a carrier gas and/or a dilution gas for the second gas. Further, the inert gas supplied through the nozzle 249a may serve to prevent invasion (backflow) of gas into the nozzle 249a.

Processing conditions in this step are exemplified as follows:
Processing temperature: 150 to 800 degrees C., specifically 180 to 700 degrees C., more specifically 400 to 700 degrees C.;
Processing pressure: 1 to 4,000 Pa, specifically 10 to 1,000 Pa;
Second gas supply flow rate: 0.1 to 20 slm, specifically 1 to 10 slm;
Second gas supply time: 1 to 120 seconds, specifically 10 to 60 seconds; and
Inert gas supply flow rate (for each gas supply pipe): 0 to 10 slm.

By supplying the second gas (reactant gas) containing the second element and H in a single molecule to the wafer 200 under the above-described conditions, at least a portion of the first layer formed on the wafer 200 is modified to form a second layer. For example, when a hydrocarbon-based gas (carbonizing agent) containing carbon (C) as the second element and H is used as the second gas, at least a portion of the first layer formed on the wafer 200 is carbonized to form the second layer. As a result, for example, a silicon carbide layer (SiC layer), which contains Si as the first element and C as the second element, is formed as the second layer on the outermost surface of the wafer 200.

In the present embodiments, a case where a hydrocarbon-based gas containing C as the second element and H is used as the second gas is described as an example.

By supplying the second gas to the wafer 200 under the above-described conditions, C—H bonds, C—C bonds, Si—C bonds, or the like are newly formed in the second layer, in addition to the Si—H bonds and Si—Cl bonds contained in the first layer described above.

After the second layer is formed, the valve 243b is closed to stop the supply of the second gas into the process chamber 201. Then, the process chamber 201 is vacuum-exhausted to remove, residual gases and the like from the process chamber 201. At this time, the valves 243f and 243g are opened to supply an inert gas into the process chamber 201, purging the process chamber 201 with the inert gas.

The second gas may be, for example, a hydrocarbon-based gas containing C as the second element and H. Examples of the hydrocarbon-based gas may include an ethylene (C₂H₄) gas, propylene (C₃H₆) gas, and butene (C₄H₈) gas. Among these, it is more desirable to use a C₃H₆ gas or C₄H₈ gas containing a methyl group as the second gas.

### [Step C]

After step B is completed, a H-containing gas, which is different from the second gas, is excited to a plasma state and then supplied to the wafer 200 within the process chamber 201, i.e., to the second layer formed on the wafer 200. In the present embodiments, step C includes a period during which the H-containing gas is supplied to the wafer 200 without plasma excitation, before supplying the plasma-excited H-containing gas to the wafer 200. In other words, in step C, step C1, in which the H-containing gas is supplied without plasma excitation, is first performed, and after a predetermined period, step C2, in which the H-containing gas within the process chamber 201 is excited into a plasma state while the supply of the H-containing gas continues, is performed. Steps C1 and C2 are described below.

### (1) Step C1

After step B is completed, a H-containing gas, which is different from the second gas, is supplied to the wafer 200 within the process chamber 201, i.e., to the second layer formed on the wafer 200.

Specifically, the valve 243d is opened to flow the H-containing gas into the gas supply pipe 232b. The H-containing gas is regulated in flow-rate by the MFC 241b and is supplied into the process chamber 201 via the nozzle 249b and then discharged from the exhaust port 231a. At this time, the H-containing gas is supplied to the wafer 200 (H-containing gas supply). At this time, the valve 243c is opened to supply the H-containing gas to the nozzle 249a. In this step, the H-containing gas supplied through the nozzle 249a serves to prevent invasion (backflow) of gas into the nozzle 249a. Further, at this time, the valves 243f and 243g are closed to stop the supply of the inert gas into the process chamber 201. In other words, in this step, the H-containing gas alone is supplied to the nozzle 249a to perform the function of preventing backflow and the like, and no gases other than the H-containing gas are supplied to the nozzle 249a. An inert gas serving as a carrier gas for the H-containing gas is also not supplied to the nozzle 249b. In particular, a N₂ gas used as an inert gas is not supplied to the nozzles 249a and 249b.

Processing conditions in this step are exemplified as follows:
Processing temperature: 150 to 800 degrees C., specifically 180 to 700 degrees C., more specifically 400 to 700 degrees C.;
Processing pressure: 2 to 100 Pa, specifically 20 to 70 Pa;
H-containing gas supply flow rate (R2): 0.05 to 20 slm;
H-containing gas supply flow rate (R1): 0.0001 to 0.003 slm; and
H-containing gas supply time (for each of R1 and R2): 1 to 100 seconds, specifically 1 to 30 seconds.

By supplying the H-containing gas to the wafer 200 under the above-described conditions, specifically, by supplying the H-containing gas to the wafer 200 through the nozzle 249b, gases (i.e., residual gases) remaining within the process chamber 201, such as N₂ gas and the second gas, other than the H-containing gas may be purged by the H-containing gas. This step may be performed, for example, until at least a portion of the residual gases within the process chamber 201 is discharged, and it is desirable for the supply time of the H-containing gas to be shorter than that in step C2. Further, in this step, the discharge of the residual gases may be promoted by regulating the APC valve 244 to increase an exhaust rate of the process chamber 201 compared to step C2.

### (2) Step C2

Once a predetermined period is passed since the start of step C1, the H-containing gas supplied into the process chamber 201 is excited into a plasma state while the supply of the H-containing gas continues.

Specifically, while the supply of the H-containing gas into the process chamber 201 via the nozzles 249a and 249b continues, RF power is applied from the RF power source 320 to the electrode 300. Thus, the H-containing gas supplied into the process chamber 201 is excited into a plasma state within the process chamber 201, generating active species such as H* or H₂*, which are then supplied to the second layer formed on the wafer 200 (plasma-excited H-containing gas supply). Consequently, the wafer 200 receives the H-containing gas containing active species such as H* or H₂*. In addition, “*” denotes a radical. This applies similarly to the following description. At this time, the valves 243f and 243g remain closed. That is, in this step, similar to step C1, the H-containing gas alone is supplied into the process chamber 201 via the nozzles 249a and 249b, and gases other than the H-containing gas are not supplied into the process chamber 201. In particular, a N₂ gas used as an inert gas is not supplied through the nozzles 249a and 249b, as in step C1.

Processing conditions in this step are exemplified as follows:
Processing temperature: 150 to 800 degrees C., specifically 180 to 700 degrees C., more specifically 400 to 700 degrees C.;
Processing pressure: 2 to 100 Pa, specifically 20 to 70 Pa;
H-containing gas supply flow rate (R2): 0.1 to 10 slm;
H-containing gas supply flow rate (R1): 0.005 to 0.03 slm;
H-containing gas supply time (for each of R1 and R2): 1 to 600 seconds, specifically 1 to 50 seconds;
RF Power: 100 to 1,000 W; and
RF frequency: 25 MHz to 35 MHz.

By supplying the plasma-excited H-containing gas to the wafer 200 under the above-described conditions, impurities such as Cl and H contained in the second layer (SiC layer) formed on the wafer 200 may be removed from the second layer by reacting them with H*, H₂*, or the like.

By supplying the H-containing gas in a plasma-excited state to the wafer 200 under the above-described conditions, the Si—H bonds or the Si—Cl bonds in the second layer are broken. H and Cl dissociated from Si desorb from the second layer, resulting in formation of dangling bonds on Si in the second layer.

Further, by supplying the H-containing gas in a plasma-excited state to the wafer 200 under the above-described conditions, the C—H bonds in the second layer are broken. H dissociated from C desorbs from the second layer, resulting in formation of dangling bonds on C in the second layer.

After removing impurities from the second layer, the valves 243c and 243d are closed to stop the supply of the H-containing gas into the process chamber 201. Further, the supply of RF power to the electrode 300 is stopped. Then, the process chamber 201 is vacuum-exhausted to remove, residual gases and the like from the process chamber 201. In addition, at this time, neither the H-containing gas nor the third gas to be described later is supplied into the process chamber 201. In the present embodiments, a step in which the process chamber 201 is exhausted without the supply of the H-containing gas and the third gas may be referred to as step E. In step E, the purge of the process chamber 201 may not be performed, and residual gases within the process chamber 201 may be removed solely by vacuum-exhaust. Alternatively, if the purge of the process chamber 201 is performed, it is desirable to supply an inert gas other than N₂ gas as a purge gas. Herein, “purge” refers to removing the active species such as H₂* and other by-products present in the process chamber 201 by supplying an inert gas into the process chamber 201. “Vacuum exhaust” refers to removing the active species such as H₂* present in the process chamber 201 without supplying an inert gas, used to purge the process chamber 201, into the process chamber 201.

The H-containing gas used in steps C1 and C2 may be, for example, a H₂ gas alone or a mixed gas containing a H₂ gas and a noble gas such as Ar gas or He gas. Any H-containing gas does not contain nitrogen (N). One or more of these may be used as the H-containing gas. That is, in step C2, the plasma-excited H₂ gas or the plasma-excited mixed gas is supplied to the wafer 200, while no plasma-excited N-containing gas is supplied to the wafer 200. Further, the H-containing gas used in step C1 may be the same as or different from the H-containing gas used in step C2.

### [Step D]

After step C is completed, the third gas, which contains the third element that is different from the first and second elements, is supplied to the wafer 200 within the process chamber 201, i.e., to the second layer formed on the wafer 200.

Specifically, the valve 243e is opened to flow the third gas into the gas supply pipe 232e. The third gas is regulated in flow-rate by the MFC 241e and is supplied into the process chamber 201 through the nozzle 249b and then discharged from the exhaust port 231a. At this time, the third gas is supplied to the wafer 200 (third gas supply). At this time, the valves 243f and 243g may be opened to supply an inert gas into the process chamber 201 through the respective nozzles 249a and 249b.

Processing conditions in this step are exemplified as follows:
Processing temperature: 150 to 800 degrees C., specifically 180 to 700 degrees C., more specifically 400 to 700 degrees C.;
Processing pressure: 1 to 4,000 Pa, specifically 10 to 1,000 Pa;
Third gas supply flow rate: 0.1 to 20 slm, specifically 1 to 10 slm;
Third gas supply time: 1 to 120 seconds, specifically 10 to 60 seconds; and
Inert gas supply flow rate (for each gas supply pipe): 0 to 10 slm.

In this step, the third gas is supplied to the wafer 200 under a non-plasma atmosphere (i.e., under a non-plasma-excited condition).

By supplying the third gas (reactant gas) containing the third element to the wafer 200 under the above-described conditions, at least a portion of the second layer formed on the wafer 200 is modified to form a third layer. For example, if a nitriding gas (nitriding agent) containing nitrogen (N) as the third element is used as the third gas, at least a portion of the second layer formed on the wafer 200 is nitrided to form the third layer. As a result, a silicon carbonitride layer (SiCN layer), which contains Si as the first element, C as the second element, and N as the third element, is formed as the third layer on the outermost surface of the wafer 200.

In the present embodiments, a case where a hydrogen nitride-based gas containing N as the third element and H is used as the third gas is described as an example.

By supplying the third gas to the wafer 200 under the above-described conditions, Si—N bonds, in which the dangling bonds on Si bond with N, and C—N bonds, in which the dangling bonds on C bond with N, are formed in the third layer.

After the third layer is formed, the valve 243e is closed to stop the supply of the third gas into the process chamber 201. Then, the process chamber 201 is vacuum-exhausted to remove residual gases and the like from the process chamber 201. At this time, the valves 243f and 243g are opened to supply an inert gas into the process chamber 201, purging the process chamber 201 with the inert gas.

The third gas may be, for example, a hydrogen nitride-based gas containing N as the third element and H. Examples of the hydrogen nitride-based gas may include an ammonia (NH₃) gas, diazene (N₂H₂) gas, hydrazine (N₂H₄) gas, and N₃H₈ gas. One or more of these may be used as the third gas.

### [Performing Cycle for Predetermined Number of Times]

By performing the cycle, in which the above-described steps A, B, C and D are preformed asynchronously, i.e., without being synchronized, a predetermined number of times (n times, n is an integer of 1, or 2 or more), a film with a predetermined thickness may be formed on the surface of the wafer 200. For example, if Si is used as the first element, C as the second element, and N as the third element as described above, a silicon carbonitride film (SiCN film) with a predetermined thickness may be formed on the surface of the wafer 200. It is desirable to repeat the above-described cycle multiple times. That is, it is desirable to make a thickness of the SiCN layer formed per cycle thinner than a desired film thickness and repeat the above-described cycle multiple times until a thickness of the SiCN film formed by stacking the SiCN layers reaches the desired thickness.

### (After-Purge and Atmospheric Pressure Recovery)

After the formation of the SiCN film with a desired thickness on the wafer 200 is completed, an inert gas serving as a purge gas is supplied into the process chamber 201 from the respective nozzles 249a and 249b and then discharged from the exhaust port 231a. Thus, the process chamber 201 is purged, removing any gases and reaction by-products remaining in the process chamber 201. Thereafter, the internal atmosphere of the process chamber 201 is replaced by the inert gas (inert gas replacement), and the internal pressure of the process chamber 201 is restored to normal pressure.

### (Boat Unloading)

Thereafter, the seal cap 219 is lowered by the boat elevator 115 to open the lower end of the manifold 209. Then, the processed wafer 200 is unloaded (boat-unloaded) from the lower end of the manifold 209 to an outside of the reaction tube 203 while being supported by the boat 217. After the boat unloading, the shutter 219s is moved, and the opening at the lower end of the manifold 209 is sealed by the shutter 219s via the O-ring 220c. The processed wafer 200 is taken out from the boat 217.

In this way, a series of processes for forming films on the wafer 200 is completed. These series of processes are performed a predetermined number of times (at least once).

### (3) Effects of Present Embodiments

According to the present embodiments, one or more of the following effects are obtained.

(a) By performing step C after steps A and B, impurities such as H and Cl derived from the first gas (H-containing chlorosilane gas) and H derived from the second gas (hydrocarbon-based gas) may be removed from the second layer (SiC layer). In this way, impurities may be effectively removed from the SiCN film. This may improve a film density of the SiCN film, resulting in enhanced ashing resistance thereof.

By performing step C after steps A and B, in step C, the Si—H bonds and Si—Cl bonds derived from the first gas, the C—H bonds derived from the second gas, or the like may be broken. In particular, H, Cl, or the like bonded with Si as well as H bonded with C may desorb from the second layer, resulting in the formation of dangling bonds, with high reactivity, on Si and C in the second layer. Thus, increasing the number of dangling bonds in the second layer may enhance reactivity with the third gas supplied in step D or reactivity with the first and second gases supplied in steps A and B of the next cycle. As a result, a film formation rate may be improved.

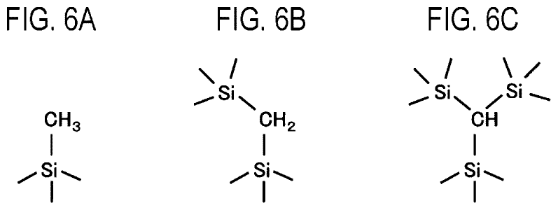

Further, by performing step C after steps A and B, in step C, the Si—H bonds and Si—Cl bonds derived from the first gas, the C—H bonds derived from the second gas, or the like may be broken. This leads to the formation of the dangling bonds on Si and C, which may bond with each other, creating stable bonds such as Si—C—Si bonds, in which the number of Si bonds with C is large, in the second layer (see FIGS. 6A and 6B). Also, by further continuing step C, more stable bonds such as the Si—C—Si bonds may be formed (see FIG. 6C). Thus, for example, even when the plasma-excited H-containing gas is supplied to the second layer formed on the wafer 200 in step C of the next cycle, desorption of C from the second layer may be prevented. This makes it possible to maintain a composition ratio of C in the SiCN film.

Furthermore, as described above, in step C, the number of the dangling bonds on Si and C in the second layer is increased, making it easier for C derived from the second gas supplied in step B of the next cycle to bond with Si and C in the second layer. As a result, the composition ratio of C in the SiCN film may be increased.

By performing step C before step D, a decrease in the composition ratio of C in the SiCN film may be prevented. This is described below.

If step C is performed after step D, the third gas (hydrogen nitride-based gas) is supplied in step D before the plasma-excited H-containing gas is supplied in step C. This leads to formation of relatively strong Si—N bonds derived from the third gas on the wafer 200. Therefore, even if, the C—H bonds and the like derived from the second gas are broken by supplying the plasma-excited H-containing gas in the subsequent step C, new Si—C bonds are unlikely to be formed, and C is likely to desorb from the second layer (SiC layer). If step C continues in this state and cleaving of C bonds (such as C—C bonds and Si—C bonds) by H₂*, etc., progresses, C may desorb from the second layer, resulting in a decrease in the composition ratio of C in the SiCN film.

Therefore, even if the number of the dangling bonds on Si and C is increased in step C to make it easier for C derived from the second gas supplied in step B of the next cycle to bond with Si and C in the second layer, the effect of maintaining or increasing the composition ratio of C in the SiCN film is limited. In addition, in step C, when C desorbs from the second layer, adsorption sites terminated by NH groups derived from the third gas on the wafer 200 are increased, and as a result, a composition ratio of N in the SiCN film tends to increase.

In the present disclosure, by performing step C before step D, highly stable bonds such as Si—C—Si bonds may be formed in the second layer before strong Si—N bonds are formed, which may prevent a decrease in the composition ratio of C in the SiCN film.

(b) In step D, by supplying the third gas to the wafer 200 in a non-plasma state (i.e., without plasma excitation), the desorption of C from the second layer may be prevented, allowing the composition ratio of C in the SiCN film to be maintained or increased.

(c) In step C, the H-containing gas supplied to the wafer 200 does not contain N and this prevents the desorption of C from the second layer while allowing the desorption of the impurities such as Cl and H, compared to using a N-containing gas. This allows highly stable bonds such as Si—C—Si bonds to be formed in the second layer, increasing the composition ratio of C in the SiCN film.

(d) In step C, the H-containing gas is supplied to the wafer 200 through the nozzle 249b (R2) and also supplied to the nozzle 249a (R1). That is, in step C, solely the H-containing gas is supplied into the process chamber 201 via the nozzles 249a and 249b, without the supply of gases other than the H-containing gas into the process chamber 201. In particular, in step C, a N₂ gas used as an inert gas is not supplied to the nozzles 249a and 249b. This may prevent a decrease in the composition ratio of C in the SiCN film.

For example, if a N-containing gas such as N₂ gas is supplied as a backflow prevention gas to the nozzle 249a in step C, the N-containing gas is plasma-excited together with the H-containing gas supplied via the nozzle 249b and then supplied to the wafer 200. At this time, active species generated by the plasma excitation of the N-containing gas are supplied to the wafer 200, causing excessive desorption of C from the second layer. This causes a decrease in the composition ratio of C in the SiCN film. In the present disclosure, by ensuring that the H-containing gas is supplied as a backflow prevention gas to the nozzle 249a in step C as described above, the excessive desorption of C from the second layer may be prevented.

(e) In step C, by performing step C1 in which the H-containing gas is supplied into the process chamber 201 before starting step C2 in which the plasma excitation of the H-containing gas is performed, gases (particularly a N-containing gas such as N₂ gas), other than the H-containing gas, remaining in the process chamber 201 may be purged by the H-containing gas. Thus, in step C2, influence of other gases, which are plasma-excited (directly excited or indirectly excited by the plasma-excited H-containing gas) together with the H-containing gas, on substrate processing may be reduced. In particular, even if the process chamber 201 is purged by a N₂ gas before step C, the N₂ gas in the process chamber 201 is purged by the H-containing gas before starting step C2, which may prevent any residual N₂ gas from being plasma-excited to desorb C from the second layer in step C2.

(f) By using the H-containing chlorosilane gas as the first gas supplied to the wafer 200 in step A, H-termination may be formed on the surface of the wafer 200 after step A, in addition to Cl-termination (halogen termination). This may increase an adsorption probability of the second gas (hydrocarbon-based gas), which is less likely to adsorb on the halogen termination.

(g) In step F, by not supplying the first and second gases, the gas-phase reaction with the first and second gases in step F may be prevented, and as a result, step coverage and composition controllability of the SiCN film may be improved.

(h) In step E, by not supplying the H-containing gas and the third gas, the desorption of C from the second layer, caused when the third gas (hydrogen nitride-based gas) is activated (indirectly excited) by H₂* or similar species generated in step C, may be suppressed. Furthermore, in step E, the desorption of C from the second layer may be prevented by supplying an inert gas, other than a N₂ gas, as a purge gas into the process chamber 201.

(i) In step C, by desorbing H and Cl bonded with Si from the second layer (SiC layer), the dangling bonds on Si may be formed. Thus, the adsorption of the third gas supplied in step D, particularly the adsorption of the first and second gases supplied in steps A and B of the next cycle to the dangling bonds on Si may be promoted.

(j) In step C, by desorbing H bonded to C from the second layer (SiC layer), the dangling bonds on C may be formed. Thus, the adsorption of the third gas supplied in step D as well as the adsorption of the first and second gases supplied in steps A and B of the next cycle to the dangling bonds on C may be promoted.

(k) By performing a cycle including step C, the composition ratio of C in the SiCN film may be made higher than a composition ratio of C in the SiCN film formed by performing a cycle including steps A, B and D but not including step C.

(l) By performing a cycle in which step C is performed before step D, the composition ratio of C in the SiCN film may be made higher than a composition ratio of C in the SiCN film formed by performing a cycle in which steps A to D are included and step C is performed after step D.

### Other Embodiments of Present Disclosure

The embodiments of the present disclosure are specifically described above. However, the present disclosure is not limited to the above-described embodiments, and may be changed in various ways without departing from the gist of the present disclosure.

In the above-described embodiments, Si, which is a semimetal element, is described as an example of the first element, but the present disclosure is not limited to this. For example, the present disclosure may be applied even when other semimetal elements such as boron (B), germanium (Ge), arsenic (As), antimony (Sb), and tellurium (Te) are used as the first element. Further, the present disclosure may also be applied when metal elements such as aluminum (Al), titanium (Ti), hafnium (Hf), zirconium (Zr), tantalum (Ta), molybdenum (Mo), and tungsten (W) are used as the first element. Further, the first gas may be, for example, a halosilane-based gas, which contains the aforementioned semimetal elements or metal elements as the first element and further contains a halogen element. In these embodiments as well, the same effects as in the above-described embodiments are obtained.

Although not particularly described in the above-described embodiments, it is desirable that the first gas be a gas that does not contain the second element. In these embodiments as well, the same effects as in the above-described embodiments are obtained. Also, in these embodiments, for example, the composition ratio of the second element in the film formed on the wafer 200 may be easily controlled by second gas supply conditions in step B.

In the above-described embodiments, an example in which the second element is C and the second gas containing the second element and H is a hydrocarbon-based gas is described, but the present disclosure is not limited to this. For example, B may be used as the second element, and a boron hydride-based gas such as monoborane (BH₃) gas or diborane (B₂H₆) gas may be used as the second gas containing the second element and H. Further, for example, B and C may be used as the second element, and both a boron hydride-based gas and a hydrocarbon-based gas described above may be used as the second gas containing the second element and H. In these embodiments as well, the same effects as in the above-described embodiments are obtained.

In the above-described embodiments, a nitriding gas (nitriding agent) containing N as the third element is described as an example of the third gas, but the present disclosure is not limited to this. For example, the present disclosure may also be applied to a case where a silicon oxycarbide film (SiOC film, i.e., a C-containing silicon oxide film), which contains Si as the first element, C as the second element, and O as the third element, is formed on the wafer 200 by using an oxidizing gas (oxidizing agent) containing oxygen (O) as the third element as the third gas. The third gas containing O may be, for example, an oxygen (O₂) gas, ozone (O₃) gas, water vapor (H₂O gas), hydrogen peroxide (H₂O₂) gas, and a mixed gas of O₂ gas and H₂ gas. One or more of these gases may be used as the third gas containing O. In these embodiments as well, at least one of the effects of the above-described embodiments are obtained.

In the above-described embodiments, an example in which the third gas is supplied to the wafer 200 under a non-plasma atmosphere in step D is described, but the present disclosure is not limited to this. For example, the third gas may be supplied to the wafer 200 under a plasma atmosphere (i.e., under a plasma excitation condition). In this case as well, it is desirable to supply the plasma-excited third gas under a condition that may prevent the desorption of C from the second layer.

It is desirable to prepare recipes used for each process individually based on process contents and to record and store them in the memory 121c via an electrical communication line or the external memory 123. Then, when starting each process, it is desirable for the CPU 121a to adequately select an appropriate recipe from among multiple recipes recorded and stored in the memory 121c based on the process contents.

The aforementioned recipes are not limited to a case of creating new recipes, and also may be prepared by modifying existing recipes already installed in the substrate processing apparatus, for example. When modifying a recipe, the recipe after modification may be installed in the substrate processing apparatus via an electrical communication line or a recording medium on which the recipe is recorded. Further, the input/output device 122 of the existing substrate processing apparatus may be operated to directly modify an existing recipe already installed in the substrate processing apparatus.

The present disclosure is not limited to the above-described embodiments, and for example, may be suitably applied even when forming a film using a single-wafer type substrate processing apparatus capable of processing one or several substrates at once. Further, the present disclosure is not limited to the above-described embodiments, and may also be suitably applied when forming a film using a substrate processing apparatus equipped with a cold-wall type process furnace. Further, in the above-described embodiments, an example in which the first to third gases are activated by heat is described. However, the present disclosure is not limited to this. For example, the present disclosure may also be suitably applied in a case where gases are activated by plasma generated inside or outside the process chamber 201, or by irradiating the gases with electromagnetic waves using a lamp or other sources.

Even when using these substrate processing apparatuses, it is possible to perform each process using the same processing procedures and processing conditions as in the above-described embodiments and modifications, and to achieve the same effects as in the above-described embodiments and modifications.

The above-described embodiments and modifications may be used in combination as appropriate. The processing procedures and processing conditions at this time may be the same as the processing procedures and processing conditions in the above-described embodiments and modifications, for example.

### EXAMPLES

As samples 1 to 3, a SiCN film was formed on a wafer using the substrate processing apparatus illustrated in FIG. 1.

Sample 1 was fabricated by performing a cycle, in which steps A, B and D are performed in this order without performing step C, n times. Sample 2 was fabricated by performing a cycle, in which steps A, B, D and C are performed in this order, n times. Sample 3 was fabricated by performing a cycle, in which steps A, B, C and D are performed in this order, n times. Processing conditions for each step in the fabrication of samples 1 to 3 were set to predetermined conditions within a range of the processing conditions for each step of the above-described embodiments.

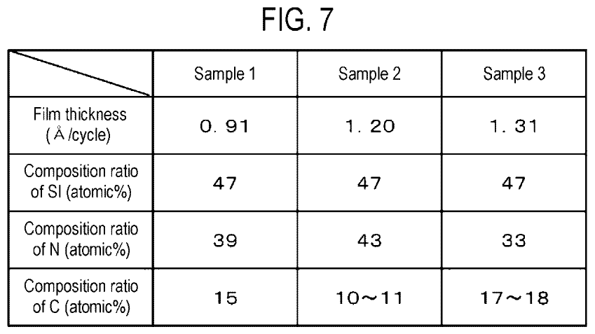

Then, a thickness of the SiCN film in each sample was measured to calculate a thickness of the SiCN film formed per cycle (Å/cycle). Further, a composition ratio (atomic %) of the SiCN film in each sample, i.e., concentrations of Si, N, and C contained in the SiCN film of each sample, was measured using X-ray photoelectron spectroscopy (XPS). These results are illustrated in FIG. 7.

As illustrated in FIG. 7, it was confirmed that the thickness of the SiCN film formed per cycle in sample 3 was greater than that in samples 1 and 2. Thus, it was found that sample 3 achieved the highest cycle rate.

As illustrated in FIG. 7, the composition ratio of Si in the SiCN film was the same for the three samples. It was confirmed that the composition ratio of N was the lowest in sample 3 and the highest in sample 2. It was confirmed that the composition ratio of C was the highest in sample 3 and the lowest in sample 2. In other words, it was confirmed that in Sample 3, the composition ratio of Si remained substantially unchanged compared to the other samples, while the composition ratio of C was significantly higher than in the other samples.

According to the present disclosure, it is possible to provide a technique capable of preventing desorption of a predetermined element during film formation and maintaining the predetermined element in a film at a desired composition ratio.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate comprising:
forming a film, which contains a first element, a second element and a third element, on the substrate by performing a cycle a predetermined number of times, the cycle including performing:
(a) supplying a first gas, which contains the first element and a halogen element, to the substrate;
(b) supplying a second gas, which contains hydrogen and the second element that is different from the first element, to the substrate;
(c) supplying a plasma-excited hydrogen-containing gas, which is different from the second gas, to the substrate; and
(d) supplying a third gas, which contains the third element that is different from the first element and the second element, to the substrate,
wherein (c) is performed after (a) and (b) and before (d).

2. The method of claim 1, wherein the second gas contains at least one selected from the group of carbon and boron, as the second element.

3. The method of claim 1, wherein the third element is nitrogen.

4. The method of claim 1, wherein the third gas is a gas containing nitrogen and hydrogen.

5. The method of claim 1, wherein in (d), the third gas is supplied to the substrate in a non-plasma state.

6. The method of claim 1, wherein the hydrogen-containing gas is a gas not containing nitrogen.

7. The method of claim 6, wherein in (a), the first gas is supplied to the substrate via a first nozzle, and
wherein in (c), the hydrogen-containing gas is supplied to the substrate via a second nozzle, which is different from the first nozzle, while the hydrogen-containing gas is also supplied to the first nozzle.

8. The method of claim 1, wherein in (c), the supply of the hydrogen-containing gas to the substrate starts before plasma excitation of the hydrogen-containing gas starts.

9. The method of claim 1, wherein the first gas is a gas containing hydrogen.

10. The method of claim 1, wherein the first element is a metal element or a semi-metal element.

11. The method of claim 1, wherein the first gas is a gas not containing the second element.

12. The method of claim 1, further comprising:
(e) between (c) and (d), exhausting a space where the substrate is present without supplying the hydrogen-containing gas and the third gas.

13. The method of claim 1, further comprising:
(f) between (a) and (b), exhausting a space where the substrate is present without supplying the first gas and the second gas.

14. The method of claim 1, wherein in (c), the halogen element bonded to the first element desorbs from a layer, which contains the first element and the second element and is formed in (b), thus forming a dangling bond on the first element.

15. The method of claim 1, wherein in (c), hydrogen bonded to the second element desorbs from a layer, which contains the first element and the second element and is formed in (b), thus forming a dangling bond on the second element.

16. The method of claim 1, wherein a ratio of the second element contained in the film containing the first element, the second element, and the third element is greater than a ratio of the second element contained in a film formed by performing a cycle that includes (a), (b) and (d) but excludes (c).

17. The method of claim 1, wherein a ratio of the second element contained in the film containing the first element, the second element, and the third element is greater than a ratio of the second element contained in a film formed by performing a cycle in which (a), (b), (d) and (c) are included and (c) is performed after (d).

18. A method of manufacturing a semiconductor device comprising the method of claim 1.

19. A non-transitory computer readable recording medium storing a program that causes, by a computer, a substrate processing apparatus to perform a process comprising forming a film, which contains a first element, a second element and a third element, on a substrate by performing a cycle a predetermined number of times, the cycle including performing:
(a) supplying a first gas, which contains the first element and a halogen element, to the substrate;
(b) supplying a second gas, which contains hydrogen and the second element that is different from the first element, to the substrate;
(c) supplying a plasma-excited hydrogen-containing gas, which is different from the second gas, to the substrate; and
(d) supplying a third gas, which contains the third element that is different from the first element and the second element, to the substrate,
wherein (c) is performed after (a) and (b) and before (d).

20. A substrate processing apparatus comprising:
a first gas supply system configured to supply a first gas, which contains a first element and a halogen element, to a substrate;
a second gas supply system configured to supply a second gas, which contains hydrogen and a second element that is different from the first element, to the substrate;
a hydrogen-containing gas supply system including a plasma exciter that plasma-excites a hydrogen-containing gas, which is different from the second gas, and configured to supply the plasma-excited hydrogen-containing gas to the substrate;
a third gas supply system configured to supply a third gas, which contains a third element that is different from the first element and the second element, to the substrate; and
a controller configured to be capable of controlling the first gas supply system, the second gas supply system, the hydrogen-containing gas supply system, and the third gas supply system to perform a process including forming a film, which contains the first element, the second element and the third element, on the substrate by performing a cycle a predetermined number of times, the cycle including performing:
(a) supplying the first gas to the substrate;
(b) supplying the second gas to the substrate;
(c) supplying the plasma-excited hydrogen-containing gas to the substrate; and
(d) supplying the third gas to the substrate,
wherein (c) is performed after (a) and (b) and before (d).
